(19) United States
(12) Patent Application Publication
(10) Pub. No.: US 2026/0031848 A1
(43) Pub. Date: Jan. 29, 2026

(54) RF DEVICE

(71) Applicant: TEXAS INSTRUMENTS INCORPORATED, Dallas, TX (US)

(72) Inventor: Rohit Chatterjee, Bangalore (IN)

(21) Appl. No.: 18/787,209

(22) Filed: Jul. 29, 2024

(51) Int. Cl. H04B 1/40; H03F 3/19; H03H 7/42

(52) U.S. Cl. CPC H04B 1/40; H03H 7/425; H03F 3/19; H03F 2200/451

(57) ABSTRACT

In an embodiment, a circuit includes a first input terminal configured to be coupled to a first terminal of a first capacitor, a second input terminal configured to be coupled to a second terminal of the first capacitor, a balun including a primary inductor and a secondary inductor, and a second capacitor. The primary inductor includes a first terminal coupled to the first input terminal, a second terminal coupled to the second input terminal, a first inductive portion coupled between the first terminal of the primary inductor and a first intermediate terminal, a second inductive portion coupled between the second terminal of the primary inductor and a second intermediate terminal, and a third inductive portion coupled between the first and second intermediate terminals. The secondary inductor includes a first terminal coupled to a ground terminal. The second capacitor is coupled between the first and second intermediate terminals.

### TECHNICAL FIELD

The present disclosure relates generally to an electronic system, and, in particular embodiments, to a radio-frequency (RF) device.

### BACKGROUND

Radio frequency (RF) devices and circuits are often used in electronic systems for communications applications. RF devices can receive and transmit radio signals at varying frequencies and with varying gain based on their design. In order to receive and transmit RF signals, RF devices often include receiver circuitry, transmitter circuitry, amplifiers, and a balun and matching network.

While operating to transmit signals in a frequency band, wireless communication protocols may limit the amount of emissions an RF device produces in other (e.g., out-of-band) frequency bands. Some existing RF devices attempt to reduce out-of-band emissions by including one or more on-board filters in the signal path to pass certification specifications in accordance with wireless communication protocols such as Wi-Fi. Some existing RF devices attempt to reduce such emissions by including an additional inductor-capacitor network that can reduce emissions at particular frequencies.

### SUMMARY

In accordance to an embodiment, a circuit includes: a first input terminal configured to be coupled to a first terminal of a first capacitor; a second input terminal configured to be coupled to a second terminal of the first capacitor; a balun including: a primary inductor that includes: a first terminal coupled to the first input terminal, a second terminal coupled to the second input terminal, a first inductive portion coupled between the first terminal of the primary inductor and a first intermediate terminal, a second inductive portion coupled between the second terminal of the primary inductor and a second intermediate terminal, and a third inductive portion coupled between the first and second intermediate terminals, and a secondary inductor that includes a first terminal coupled to a ground terminal; and a second capacitor coupled between the first and second intermediate terminals.

In accordance to an embodiment, a circuit includes: a first capacitor including first and second terminals, and a first set of conductive features; a first input terminal coupled to the first terminal of the first capacitor; a second input terminal coupled to the second terminal of the first capacitor; a balun including: a secondary inductor that includes: a first terminal coupled to a ground terminal; and a second set of conductive features; and a primary inductor that includes: a first terminal coupled to the first input terminal; a second terminal coupled to the second input terminal; and a third set of conductive features proximate to the second set of conductive features of the secondary inductor; and a second capacitor that includes a fourth set of conductive features proximate to the first and second sets of conductive features and disposed such that the fourth set of conductive features are positioned within an area inside the second and third sets of conductive features; where the third set of conductive features of the primary inductor includes: a first subset of conductive features coupled between the first terminal of the primary inductor and a first intermediate terminal; a second subset of conductive features coupled between the second terminal of the primary inductor and a second intermediate terminal; and a third subset of conductive features coupled between the first and second intermediate terminals; and where the fourth set of conductive features of the second capacitor are coupled between the first and second intermediate terminals.

In accordance to an embodiment, an integrated circuit includes: a balun including: a primary inductor that includes: a center-tap terminal, first and second input terminals, first and second intermediate terminals, a first metal track coupled between the center-tap terminal and the first intermediate terminal, a second metal track coupled between the center-tap terminal and the second intermediate terminal, a third metal track coupled between the first intermediate terminal and the first input terminal, and a fourth metal track coupled between the second intermediate terminal and the second input terminal, a secondary inductor that includes a ground terminal and an output terminal; and a first capacitor coupled between the first and second intermediate terminals.

In accordance to an embodiment, an electronic circuit includes: a phase-locked loop (PLL) circuit; and a transmitter circuit coupled to the PLL circuit, where the transceiver circuit includes: an amplifier; and an impedance-matching circuitry coupled to the amplifier circuitry, where the impedance-matching circuitry includes: a first input terminal configured to be coupled to a first terminal of a first capacitor; a second input terminal configured to be coupled to a second terminal of the first capacitor; and a balun including: a primary inductor that includes: a first terminal coupled to the first input terminal, a second terminal coupled to the second input terminal, a first inductive portion coupled between the first terminal of the primary inductor and a first intermediate terminal, a second inductive portion coupled between the second terminal of the primary inductor and a second intermediate terminal, and a third inductive portion coupled between the first and second intermediate terminals, and a secondary inductor that includes a first terminal coupled to a ground terminal; and a second capacitor coupled between the first and second intermediate terminals.

### BRIEF DESCRIPTION OF THE DRAWINGS

For a more complete understanding of the present invention(s), and the advantages thereof, reference is now made to the following descriptions taken in conjunction with the accompanying drawings, in which:

FIG. 1 illustrates an example transceiver system that may be used in accordance with an embodiment;

FIG. 2 illustrates an example circuit that may be used in a transceiver system in accordance with an embodiment;

FIG. 3 illustrates aspects of conductive features used in a balun circuit of a transceiver circuit in accordance with an embodiment; and

FIGS. 4, 5, 6, and 7 illustrate example graphical representations of waveforms produced by a transceiver system in accordance with an embodiment.

Corresponding numerals and symbols in different figures generally refer to corresponding parts unless otherwise indicated. The figures are drawn to clearly illustrate the relevant aspects of the preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the invention(s), and do not limit the scope of the invention(s).

The description below illustrates the various specific details to provide an in-depth understanding of several example embodiments according to the description. The embodiments may be obtained without one or more of the specific details, or with other methods, components, materials and the like. In other cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Embodiments of the present disclosure will be described in specific contexts, e.g., a transformer topology of a transceiver, a balun topology of a transceiver, e.g., a topology used to reduce odd-harmonic frequency emissions, e.g., reducing frequency emissions while using communication protocols such as Bluetooth Classic, Bluetooth Low Energy (BLE), Wi-Fi, or Ultrawide Band (UWB). Some embodiments may be used in other wireless communications, reception, and transmission applications, as well as using other wireless communication protocols. Some embodiments may be used in other applications, such as millimeter-wave radar. Some embodiments may be used in RF applications to reduce emissions at other frequencies or frequency bands (e.g., different from the odd harmonics).

Some embodiments relate to enhanced components, techniques, and systems related to radio frequency (RF) circuits, and more particularly, to reducing out-of-band emissions produced by an RF circuit using a transformer topology that includes a capacitor coupled across a primary coil of a transformer of a balun structure within the RF circuit. RF circuits may be designed to receive and transmit radio signals at varying frequencies and with variable gain. In such devices, an amplifier (e.g., a power amplifier) may be included to provide a signal from the RF circuit to the antenna without significant insertion loss, noise, or other issues. In embedded systems, such as systems-on-chip (SoCs), various elements of a system may be coupled together using conductive features and through pins, pads, and/or ports of the elements. In such systems, to provide impedance matching or impedance transformation functionality, existing RF circuit designs often include an on-board or on-chip impedance matching network, or balun, coupled to outputs of the amplifier. One or more filters may also be included in such systems to reduce emissions at particular frequencies in accordance with wireless communication regulations. In some such designs, including multiple filters to reduce emissions may increase cost and design area requirements on the SoC, especially when large magnitudes of noise or harmonic emissions are required to be filtered at the system.

Some embodiments relate to a circuit that includes a balun that can reduce emissions at particular frequencies, such that filter circuits of a system may be reduced in size, quantity, or quality (or eliminated) as a result of filtering and attenuation capabilities added by the balun. In some examples, the balun can reduce emissions at one or more odd-harmonic frequencies, such as the third harmonic, the fifth harmonic, the seventh harmonic, or other harmonics with respect to a target output frequency. The balun may include a transformer and multiple capacitors, one of which may be coupled across portions of a first inductor of the transformer, which may be configured to reduce emissions at one or more of the odd-harmonic frequencies based on introducing a zero at the one or more of the odd-harmonic frequencies. In this way, the capacitor coupled across the inductor of the transformer may attenuate noise attributed to odd-harmonic frequencies. Advantageously, in some embodiments, the balun can perform filtering of particular frequencies, such that the filter circuits may be eliminated or simplified in design, which may advantageously decrease cost and increase design area available for other components of a system.

In an example embodiment, a circuit comprises a first input terminal, a second input terminal, a balun, and a second capacitor is provided. The first input terminal is configured to be coupled to a first terminal of a first capacitor. The second input terminal is configured to be coupled to a second terminal of the first capacitor. The balun comprises a primary inductor and a secondary inductor. The primary inductor includes first terminal coupled to the first input terminal, a second terminal coupled to the second input terminal, a first inductive portion coupled between the first terminal of the primary inductor and a first intermediate terminal, a second inductive portion coupled between the second terminal of the primary inductor and a second intermediate terminal, and a third inductive portion coupled between the first and second intermediate terminals. The secondary inductor includes a first terminal coupled to a ground terminal. The second capacitor is coupled between the first and second intermediate terminals.

In another example embodiment, a circuit is provided that includes a first capacitor including first and second terminals and a first set of conductive features, a first input terminal coupled to the first terminal of the first capacitor, a second input terminal coupled to the second terminal of the first capacitor, a balun, and a second capacitor. The balun includes a secondary inductor that includes a first terminal coupled to a ground terminal and a second set of conductive features and a primary inductor that includes a first terminal coupled to the first input terminal, a second terminal coupled to the second input terminal, and a third set of conductive features proximate to the second set of conductive features of the secondary inductor. The fourth set of conductive features of the second capacitor are proximate to the first and second set of conductive features and are disposed such that the fourth set of conductive features are positioned within an area inside the second and third sets of conductive features. The third set of conductive features of the primary inductor include a first subset of conductive features coupled between the first terminal of the primary inductor and a first intermediate terminal, a second subset of conductive features coupled between the second terminal of the primary inductor and a second intermediate terminal, and a third subset of conductive features coupled between the first and second intermediate terminals. The fourth set of conductive features of the second capacitor are coupled between the first and second intermediate terminals.

In yet another example embodiment, an integrated circuit including a balun and a first capacitor is provided. The balun includes a primary inductor and a second inductor that includes a ground terminal and an output terminal. The primary inductor includes a center-tap terminal, first and second input terminals, first and second intermediate terminals, a first metal track coupled between the center-tap terminal and the first intermediate terminal, a second metal track coupled between the center-tap terminal and the second intermediate terminal, a third metal track coupled between the first intermediate terminal and the first input terminal, and a fourth metal track coupled between the second intermediate terminal and the second input terminal. The first capacitor is coupled between the first and second intermediate terminals.

In yet another example embodiment, an electronic circuit is provided that includes a phase-locked loop (PLL) circuit and a transceiver circuit coupled to the PLL circuit. The transceiver circuit includes amplifier circuitry and impedance-matching circuitry coupled to the amplifier circuitry. The impedance-matching circuitry includes a first input terminal configured to be coupled to a first terminal of a first capacitor, a second input terminal configured to be coupled to a second terminal of the first capacitor; and a balun that includes a primary inductor and a second inductor. The primary inductor includes a first terminal coupled to the first input terminal, a second terminal coupled to the second input terminal, a first inductive portion coupled between the first terminal of the primary inductor and a first intermediate terminal, a second inductive portion coupled between the second terminal of the primary inductor and a second intermediate terminal, and a third inductive portion coupled between the first and second intermediate terminals. The secondary inductor includes a first terminal coupled to a ground terminal. The second capacitor is coupled between the first and second intermediate terminals.

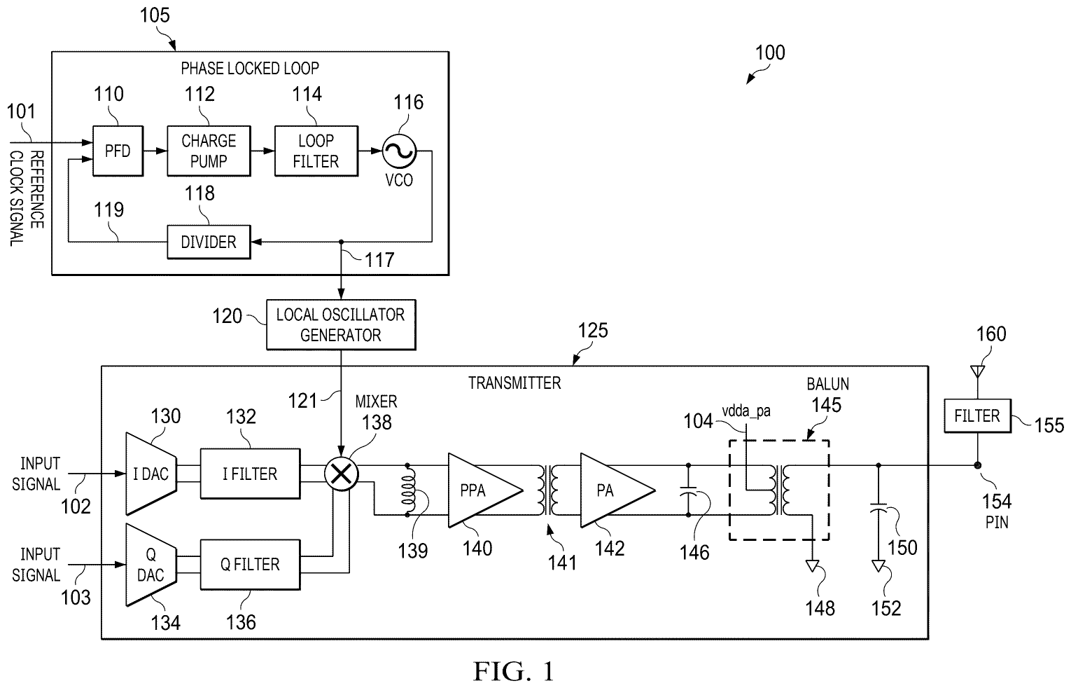

FIG. 1 illustrates an example transceiver system that may be used in accordance with an embodiment. FIG. 1 shows operating environment 100, which includes phase locked loop (PLL) 105, local oscillator generator 120, transmitter 125, and filter 155, and antenna 160. PLL 105 may include phase frequency detector (PFD) 110, charge pump 112, loop filter 114, voltage-controlled oscillator (VCO) 116, and divider 118. Transmitter 125 may include digital-to-analog converters (DACs) 130 and 134, filters 132 and 136, mixer 138, amplifier 140, transformer 141, amplifier 142, and balun 145.

The system shown in operating environment 100 is representative of a radio frequency (RF) system capable of processing signals received by or transmitted from antenna 160 for downstream usage. In various embodiments, PLL 105, transmitter 125, and filter 155 of the system may be representative of one or more circuits (e.g., an electronic circuit) integrated on-chip (e.g., a system-on-chip (SoC)). In some such embodiments, one or more of the circuits may be located off-chip relative to other components. Additionally, in some such embodiments, antenna 160 may be located off-chip relative to the circuits and may be coupled to the circuits at pin/pad 154. The system may employ one or more types of conductive traces, strips, solder types, dielectric materials, and other components to perform signal reception, signal transmission, and processing functionality. For example, the system may be employed to receive or transmit and process radar data from antenna 160. Other uses may be contemplated. In some embodiments, the system may include additional or fewer components than shown with respect to FIG. 1.

PLL 105 is included and may be representative of one or more circuits configured to process input signals and generate output signals to be used by local oscillator generator 120. More specifically, PLL 105 can be configured to receive reference clock signal 101 as an input and perform signal processing operations using reference signal 101 to generate an output signal with a target frequency and/or a target phase. In some embodiments, the signal processing operations may include generating higher output frequency signals based on reference clock signal 101, modulating, demodulating, and/or filtering the reference clock signal 101, and the like. In operating environment 100, PLL 105 may include PFD 110, charge pump 112, loop filter 114, VCO 116, and divider 118. In some embodiments, PLL 105 may include additional or fewer components. PLL 105 may be implemented in any way known in the art.

PFD 110 may be representative of a circuit configured to obtain reference signal 101 and feedback signal 119 from divider 118, perform a comparison between the signals with respect to frequency and phase, and output a signal to, e.g., charge pump 112. PFD 110 may be implemented in any way known in the art.

Charge pump 112 may be representative of a circuit configured to obtain an output signal from PFD 110, increase or decrease the voltage of the signal based on a value of the signal (i.e., determined based on the comparison of frequency and/or phase of the reference signal 101 and feedback signal 119), and output a signal to loop filter 114. Charge pump 112 may be implemented in any way known in the art.

Loop filter 114 may be representative of a circuit configured to filter noise from the voltage output signal from charge pump 112 and provide a filtered signal to VCO 116. In some examples, loop filter 114 may include a low-pass filter. In some examples, loop filter 114 may include other types of filters, such as a high-pass filter, a band-pass filter, an active filter, and the like, or combinations or variations thereof. Loop filter 114 may be implemented in any way known in the art.

VCO 116 may be representative of a circuit configured to convert the voltage of an input signal from loop filter 114 to a target frequency. In some examples, VCO 116 may operate at a particular reference frequency (e.g., approximately 6.4 GHz), generate output signal 117 based on the reference frequency and the signal input to VCO 116 from loop filter 114, and provide output signal 117 to divider 118 and to local oscillator generator 120. VCO may be implemented in any way known in the art.

Divider 118 may be representative of a circuit configured to obtain output signal 117 from VCO 116, divide the frequency of output signal 117 to a PFD frequency associated with PFD 110, and provide feedback signal 119 to PFD 110. Divider 118 may be implemented in any way known in the art.

Local oscillator generator 120 may be representative of a circuit configured to obtain output signal 117 from VCO 116, generate local oscillator (LO) clock signal 121 based on output signal 117, and provide LO clock signal 121 to transmitter 125, or more particularly, to mixer 138 thereof. In various embodiments, local oscillator generator 120 may be representative of a timing or clock signal generation signal including one or more oscillators. In some embodiments, local oscillator generator 120 may generate a differential clock signal. In some such embodiments, local oscillator generator 120 may include two outputs coupled to two respective inputs of mixer 138. Local oscillator generator 120 may be implemented in any way known in the art.

Transmitter 125 may be representative of a circuit capable of transmitting signals via antenna 160 using a transmitter path, and receiving signals from antenna 160 using a receiver path (not shown).

In operating environment 100, transmitter 125 may be configured to operate as a transmitter capable of receiving input signals 102 and 103 and LO clock signal 121, processing input signals 102 and 103 based on LO clock signal 121, and outputting signals for transmission via antenna 160. In various embodiments, such processing operations may include converting input signals 102 and 103, filtering and mixing signals based on input signals 102 and 103, amplifying signals based on input signals 102 and 103, and performing impedance matching operations, among other processing operations. To do so, transmitter 125 may include amplifier circuitry and impedance-matching circuitry, such as DACs 130 and 134, filters 132 and 136, mixer 138, amplifier 140, transformer 141, amplifier 142, and balun 145. In some embodiments, transmitter 125 may include additional or fewer components. In some embodiments, transmitter 125 may be part of a larger device or circuit, such as a transceiver, that includes additional circuitry for receiving signals from antenna 160 as well as transmitting signals via antenna 160.

DACs 130 and 134 may be representative of digital-to-analog conversion circuitry coupled to receive input signals 102 and 103 (i.e., digital input signals), respectively, and convert the analog input signals to analog signals, which are then filtered by filters 132 and 136 to remove noise and harmonics created during the digital to analog conversion process. Filters 132 and 136 may be representative of one or more circuits capable of filtering analog signals provided by DACs 130 and 134, respectively. In some embodiments, filters 132 and 136 may be representative of intermediate frequency (IF) filters. DAC 130 and filter 132 may be configured to perform respective operations on input signal 102, and DAC 134 and filter 136 may be configured to perform respective operations on input signal 103. In some embodiments, input signal 102 may include a signal having a first phase, and input signal 103 may include a signal having a second phase 90-degrees out-of-phase relative to the phase of input signal 102. In this way, DACs 130 and 134 and filters 132 and 136 may perform quadrature signal generation based on input signals 102 and 103, respectively, and provide digital signals based on performing the quadrature signal generation to mixer 138. In some embodiments, input signals 102 and 103 may be differential digital signals, and DACs 130 and 134 and filters 132 and 136 may perform respective operations on differential signals and output differential signals to mixer 138. The DACs and filters may be implemented in any way known in the art.

Mixer 138 may be representative of a circuit capable of combining two or more signals in operating environment 100, such as the signals from filters 132 and 136, based on LO clock signal 121, to produce differential mixed signals (e.g., up-converted signals) for use by amplifier 140. More specifically, mixer 138 may be configured to receive differential signals from filter 132, differential signals from filter 136, LO clock signal 121 from local oscillator generator 120 and generate output signals based on the received input signals. Mixer 138 may be implemented in any way known in the art.

Inductor 139 may be coupled to outputs of mixer 138 and to inputs of amplifier 140. More specifically, inductor 139 may include a first terminal coupled to a first output of mixer 138 and to a first input of amplifier 140 and a second terminal coupled to a second output of mixer 138 and to a second input of amplifier 140.

Amplifier 140 may be representative of amplifier circuitry capable of receiving the differential signals from mixer 138 at the two inputs of amplifier 140, amplifying the differential signals, and outputting amplified differential signals at outputs of amplifier 140 to transformer 141. In some embodiments, amplifier 140 may be a power amplifier, a pre-power amplifier, a low-noise amplifier, or another type of amplifier. Amplifier 140 may be implemented in any way known in the art.

Transformer 141 may be representative of a transformer circuit capable of transferring signals output from amplifier 140 to amplifier 142, e.g., with an increase in voltage, a decrease in voltage, or the same voltage. Transformer 141 may include a first inductor coupled to the outputs of amplifier 140 and a second inductor coupled to inputs of amplifier 142. Transformer 141 may be implemented in any way known in the art.

Amplifier 142 may be representative of a circuit capable of receiving differential signals amplified by amplifier 140 and transferred to amplifier 142 via transformer 141 and further amplifying the differential signals for transmission via antenna 160. In some embodiments, amplifier 142 may be a power amplifier, a low-noise amplifier, or another type of amplifier. Amplifier 142 may be implemented in any way known in the art.

Balun 145 may be coupled across the outputs of amplifier 142 and may be representative of impedance-matching circuitry capable of providing an interface between amplifier 142 and antenna 160 that can match the impedance of the antenna signals, provide maximum power transfer between amplifier 142 and antenna 160, and provide filtering capabilities with respect to emissions at one or more target frequencies prior to and during transmission of signals via antenna 160.

Balun 145 may be coupled to capacitor 146 and capacitor 150. Capacitor 146 may include a first terminal coupled to a first output of amplifier 142 and to a first terminal of balun 145 and a second terminal coupled to a second output of amplifier 142 and to a second terminal of balun 145. Capacitor 150 may include a first terminal coupled to a third terminal and to filter 155 and a second terminal coupled to ground terminal 152. Balun 145 may include a first inductor coupled to the first terminal and to the second terminal, and a second inductor electromagnetically coupled to the first inductor, including a first terminal coupled to the third terminal and to filter 155 and a second terminal coupled to ground terminal 148. One or more capacitors may be coupled to the first inductor. Supply power 104 may be provided to balun 145, such as to a center tap terminal of the first inductor.

In some embodiments, the one or more capacitors coupled to the first inductor may include a split-capacitor device including two or more capacitors coupled in series with each other. In an example where the split-capacitor device includes two capacitors, a first capacitor of the split-capacitor device may include a first terminal coupled to a first tap terminal of the first inductor and a second terminal coupled to a first terminal of the second capacitor of the split-capacitor device. The second terminal of the second capacitor may be coupled to a second tap terminal of the first inductor. In some such embodiments, the split-capacitor device may be included to reduce lead inductance between the capacitor and turns of the balun 145, and thus, the terminals of the capacitors of the split-capacitor device may be short in length.

In some embodiments, the one or more capacitors coupled to the first inductor may include a single capacitor including a first terminal coupled to the first tap terminal of the first inductor and a second terminal coupled to the second tap terminal of the first inductor.

Regardless of implementation, the first tap terminal of the first inductor may be a terminal located on the first inductor between the first terminal of balun 145 and the center tap terminal of the first inductor (also referred to as the first intermediate terminal), and the second tap terminal of the first inductor may be a terminal located on the first inductor between the second terminal of balun 145 and the center tap terminal of the first inductor (also referred to as the second intermediate terminal). In some embodiments, the relative inductance (or relative distance) n between the first intermediate terminal and the second intermediate terminal as compared to the total inductance (or relative distance) between the first terminal and the second terminal may be half (e.g., n=0.5). In some embodiments, the relative inductance (or relative distance) between the first intermediate terminal and the second intermediate terminal may be greater or lesser than half the inductance (or relative distance) between the first terminal and the second terminal (e.g., n≠0.5). In some such embodiments, the first and the second intermediate terminals may be closer to the center tap terminal as compared to the first and the second terminals.

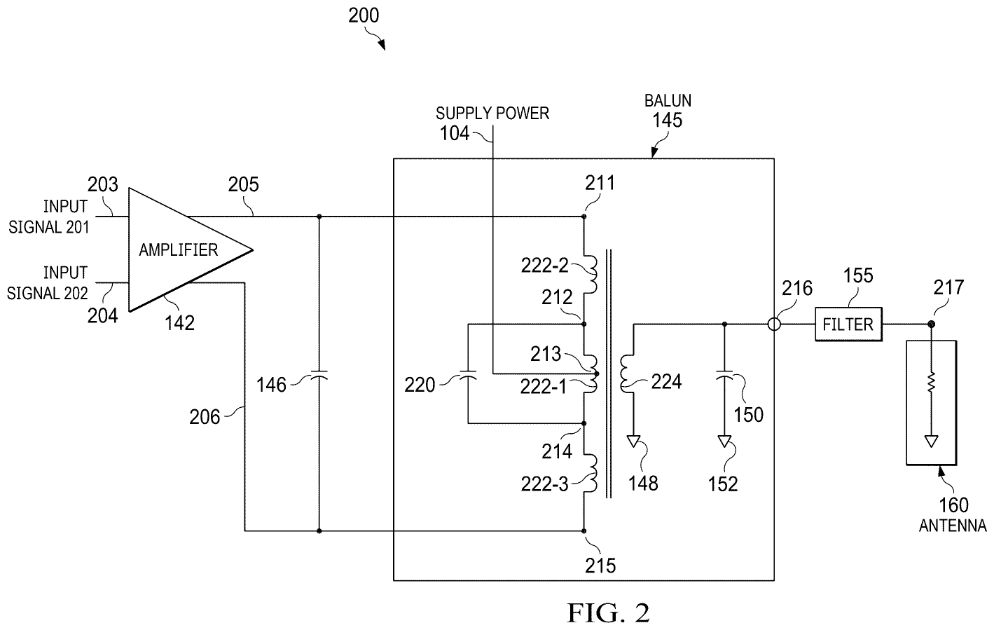

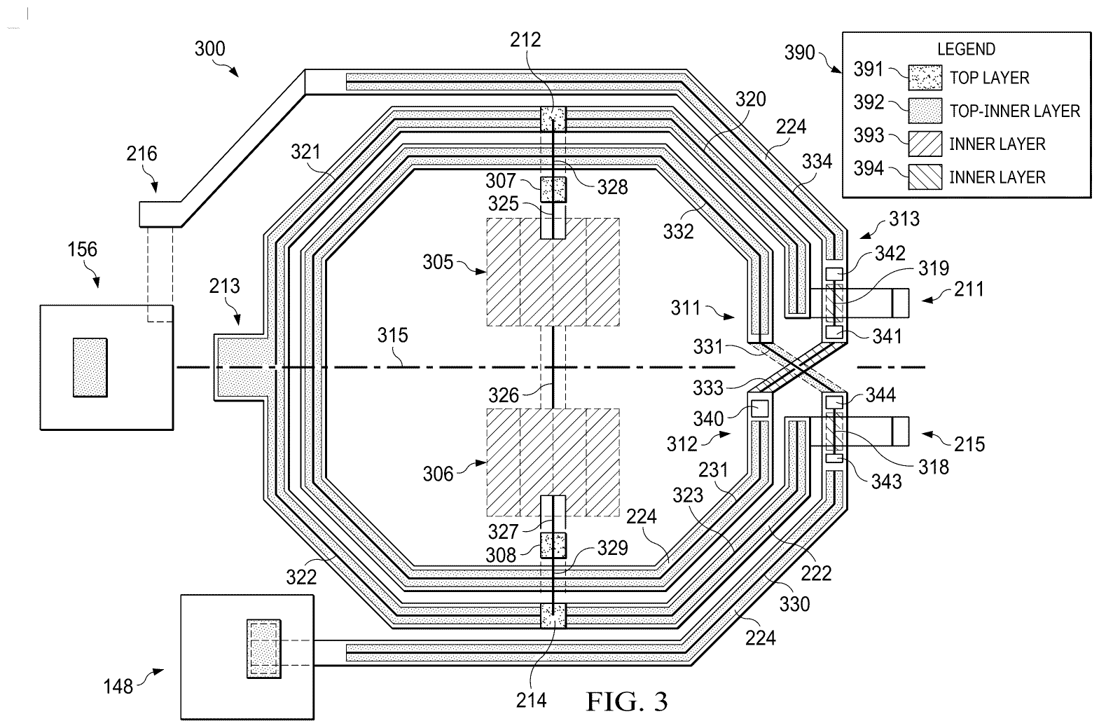

In various embodiments, the relative inductance or distance may be determined based on the target transmission frequency (e.g., approximately 2.412 GHz to 2.484 GHZ when using a WiFi communication protocol, e.g., approximately 2.40 GHz to 2.484 GHZ when using a Bluetooth communication protocol (e.g., BLE)) of antenna 160 and based on desired filtering of a target harmonic frequency of the target transmission frequency (e.g., the third odd-harmonic frequency of the target transmission frequency). More specifically, in some such embodiments, the inductances or distances may be selected to cause a notch in a frequency response at one or more frequencies corresponding to one or more odd-order harmonics of a transmission frequency (e.g., an odd-order harmonic of the transmission frequency, e.g., the third harmonic frequency, e.g., approximately 7.344 GHZ). Additionally, in some such embodiments, the inductances or distances may be selected to influence the gain at one or more odd-order and/or even-order harmonics of the transmission frequency. In various embodiments, the capacitance values of the one or more capacitors, among other components and respective values of balun 145, may be determined based on the target transmission frequency and the target harmonic frequency of the target transmission frequency. Additional details of balun 145 are illustrated and described with respect to FIGS. 2 and 3 below.

Filter 155 may be representative of one or more filter circuits capable of filtering noise and emissions at particular frequencies. In some examples, filter 155 may include a (e.g., passive) low-pass filter, and may include resistor(s), capacitor(s), and/or inductors. In some examples, filter 155 may include other types of filters, such as a high-pass filter, a band-pass filter, an active filter, and the like, or combinations or variations thereof. Filter 155 may be implemented in any way known in the art. However, based on the topology and filtering capability of balun 145, in some embodiments filter 155 may include fewer components as filtering requirements may be reduced. In some embodiments, filter 155 might not be included in operating environment 100.

Antenna 160 may be representative of an antenna coupled to the SoC at pin 154 and capable of transmitting signals over the air and/or receiving signals over the air and converting the signals to electrical currents. Antenna 160 may operate in various bandwidths and radio frequencies (e.g., 2.4 GHz to 2.4835 GHz, e.g., 2.412 GHz to 2.484 GHz, e.g., 3.1 GHz to 10.6 GHz), such as in narrow-band or wide-band, in accordance with one or more communication protocols (e.g., Bluetooth Classic, BLE, Wi-Fi, UWB, IEEE 802.11ax (as well as preceding protocols), etc.). Antenna 160 may be coupled to receive signals from transmitter 125 and transmit RF signals at a target frequency to downstream systems or devices. In some embodiments, antenna 160 may also be configured to receive signals and provide electrical signals based on the received signals to transmitter 125 or to another receiver circuit.

In some embodiments, operating environment 100, and components thereof, may include additional or fewer elements. For example, in some embodiments, operating environment 100 may include various metal traces, metal tracks, conductive features, and the like, such as bond-wires that couple elements of operating environment 100 together.

FIG. 2 illustrates an example circuit that may be used in a transceiver system in accordance with an embodiment. FIG. 2 shows circuit 200, which may include and reference elements of system 100 of FIG. 1. For example, circuit 200 includes amplifier 142, balun 145, filter 155, and antenna 160 of system 100. Circuit 200 also includes capacitors 146, 150 and 220. Balun 145 includes inductors 222 and 224, and various terminals.

In circuit 200, amplifier 142 includes inputs 203 and 204 and outputs 205 and 206. Inputs 203 and 204 may be coupled to receive input signals 201 and 202, respectively. Input signals 201 and 202 may be representative of differential signals amplified and output by amplifier 140 of operating environment 100 and provided to amplifier 142 via transformer 141 of operating environment 100. Amplifier 142 may be configured to amplify input signals 203 and 204 and generate output signals at outputs 205 and 206. Outputs 205 and 206 of amplifier 142 may be coupled to balun 145 at terminals 211 and 213 of balun, respectively.

Balun 145 may be coupled to capacitor 146 and 150. Capacitor 146 includes a first terminal coupled to output 205 of amplifier 142 and to terminal 211 and a second terminal coupled to output 206 of amplifier 142 and to terminal 213. Balun 145 includes inductors 222 and 224. Inductor 222 may include three portions, inductor portions 222-1, 222-2, and 222-3, subdivided based on tap terminals 212 and 214, and inductor 224. While illustrated in FIG. 2 as three individual inductors coupled in series, in various embodiments, inductor 222 may be a single inductor electromagnetically coupled to inductor 224. In some embodiments, inductor 222 may include three individual inductors coupled together in series. Inductor 224 may include a first terminal coupled to terminal 216 (e.g., pin/pad 154) and a second terminal coupled to ground terminal 152. In some embodiments, inductor 222 may be referred to as the primary inductor, while inductor 224 may be referred to as the secondary inductor.

Balun 145 may be coupled to capacitor 150 and to filter 155 at terminal 216. Capacitor 150 may include a first terminal coupled to terminal 216 and a second terminal coupled to ground terminal 152. Filter 155 may be configured to couple to antenna 160 at terminal 217.

Inductor 222 includes a first terminal coupled to capacitor 146 and to output 205 at terminal 211 and a second terminal coupled to capacitor 146 and to output 206 at terminal 215. Inductor 222 also includes center tap terminal 213 coupled to receive supply power 104. In some embodiments, supply power 104 may include a voltage output by a power supply that also supplies power to other elements of circuit 200, among other systems. In some embodiments, supply power 104 may be a voltage also supplied to amplifier 142. Center tap terminal 213 may be a terminal located at a midpoint of inductor 222, and more specifically, at a midpoint of inductor portion 222-1 of inductor 222.

Capacitor 220 may include a first terminal coupled to inductor 222 at terminal 212, or more specifically, at a location between inductor portion 222-1 and inductor portion 222-2 and a second terminal coupled to inductor 222 at terminal 214, or more specifically, at a location between inductor portion 222-1 and 222-3.

In some embodiments, capacitor 222 may be implemented as a split-capacitor device including two or more capacitors coupled in series with each other. In some such embodiments, a first capacitor of capacitor 220 may include a first terminal coupled to inductor 222 at terminal 212 and a second terminal coupled to a first terminal of the second capacitor of capacitor 220. The second terminal of the second capacitor may be coupled to inductor 222 at terminal 214. In some such embodiments, the split-capacitor device may be included inside balun 145, e.g., which may advantageously result in traces of short length to couple capacitor 220 to balun 145, which may advantageously reduce lead inductance from the capacitor 220 to the turns of balun 145.

In some embodiments, capacitor 222 may be implemented as a single capacitor that includes only two plates disposed within the turns of balun 145. In some such embodiments, the capacitor 222 may be implemented to maximize the length of the plates such that the distance between the plates and the terminal of balun 145 is short (with the width of such plates adjusted to obtain a desired capacitance).

Regardless of implementation, in various embodiments, terminal 212 may be a terminal located on inductor 222 between terminal 211 and center tap terminal 213 (e.g., a first intermediate terminal), and terminal 214 may be a terminal located on inductor 222 between terminal 215 and center tap terminal 213 (e.g., a second intermediate terminal).

In some embodiments, the relative inductance (or relative distance) n between the first intermediate terminal and the second intermediate terminal as compared to the total inductance (or relative distance) between the first terminal and the second terminal may be half (e.g., n=0.5). In some embodiments, the relative inductance (or relative distance) between the first intermediate terminal and the second intermediate terminal may be greater or lesser than half the inductance (or relative distance) between the first terminal and the second terminal (e.g., n≠0.5). In some such embodiments, the first and the second intermediate terminals may be closer to the center tap terminal as compared to the first and the second terminals.

In some embodiments, inductor 222 may be implemented in circuit 200 with metal tracks. As such, inductor portions 222-1, 222-2, and 222-3 may each be a portion of the metal tracks. In some such embodiments, based on the distances between respective terminals, inductor portions 222-2 and 222-3 may include metal tracks of the same lengths, and 222-1 may be equal to the sum of the lengths of 222-2 and 222-3. In some such embodiments, based on the distances between respective terminals, inductor portions 222-1, 222-2, and 222-3 may include metal tracks of different lengths. In some such embodiments, inductor 222 may be broken up into further portions, such as a portion between terminal 211 and 212, a portion between terminal 212 and center tap terminal 213, a portion between center tap terminal 213 and terminal 214, and a portion between terminal 214 and terminal 215.

In various embodiments, the lengths of 222-1, 222-2 and 222-3 (e.g., and the value of n) may be determined based on the target transmission frequency (e.g., approximately 2.412 GHz to 2.484 GHz, approximately 2.40 GHz to 2.484 GHZ) of antenna 160 and based on desired filtering of a target harmonic frequency of the target transmission frequency (e.g., filtering at the third odd-harmonic frequency of the target transmission frequency). In some such embodiments, the relative inductance or distance may be selected to cause a notch in a frequency response of circuit 200 at one or more frequencies corresponding to one or more odd and/or even-order harmonics of the target transmission frequency. Additionally, the capacitance values of capacitor 220 and capacitor 146 may be determined based on the target transmission frequency and the target harmonic frequency of the target transmission frequency which may be attenuated.

The following equation may be used to determine the input impedance of the balun 145 measured across capacitor 146, with which pole frequencies and zero frequencies at target harmonic frequencies may be found, where Lo is the inductance of inductor 222, n is the relative inductance of 222-1 as compared to the total inductance of 222, where n is a value between 0 and 1, C₁ is the capacitance of capacitor 220, C₂ is the capacitance of capacitor 146, and ω is the angular frequency:

$${Z}_{out} = \frac{j ω {L}_{0} * [ 1 - n {ω}^{2} ( 1 - n ) {L}_{0} {C}_{1} ]}{1 - {ω}^{2} {L}_{0} * ( n {C}_{1} + {C}_{2} ) + {ω}^{4} n ( 1 - n ) {L}_{0}^{2} {C}_{1} {C}_{2}}$$

The following equations may be used to determine the inductance of each inductor portion of inductor 222, where L₂₂₂₋₁ is the inductance of inductor portion 222-1, L₂₂₂₋₂ is the inductance of inductor portion 222-2, and L₂₂₂₋₃ is the inductance of inductor portion 222-3:

$${L}_{222 - 1} = {L}_{0} * n {L}_{222 - 2} = {L}_{0} * \frac{( 1 - n )}{2} {L}_{222 - 3} = {L}_{0} * \frac{( 1 - n )}{2}$$

In some embodiments, n and C₁ may be determined to place a zero at a target harmonic frequency (e.g., the third harmonic frequency) of a target transmission frequency and a pole at a different target harmonic frequency (e.g., the fifth harmonic frequency) of the target transmission frequency. Additionally, C₂ may be determined to place a pole at the target transmission frequency. In some such embodiments, C₂ may be based on C₁.

In an example embodiment, Lo may be approximately 550 pH, C₁ may be approximately 3.2 pF, C₂ may be approximately 3.0 pF, and n may be 0.5, such that the distance between terminal 212 and terminal 214 is half the distance between terminal 211 and terminal 215. In some such embodiments, the selection of n and C₁ may place a zero at the third harmonic frequency (e.g., approximately 7.5 GHZ) of a target transmission frequency (e.g., approximately 2.412-2.484 GHz). In some embodiments, C1 may be set to 1.2 pF to place the zero instead at the fifth harmonic frequency (e.g., approximately 12.5 GHZ) or to 0.6 pF to place the zero at the seventh harmonic frequency (e.g., approximately 17.5 GHZ).

Thus, in operation, based on values of capacitors 146 and 220, inductor 222, and the locations of terminals 212 and 214 with respect to center tap terminal 213 and with respect to each other, balun 145 may provide filtering capabilities to reduce or eliminate emissions at particular target harmonic frequencies of a target transmission frequency. Advantageously, out-of-band emissions transmitted by antenna 160 may be reduced, which may result in filtering of such emissions satisfactorily with respect to communication protocol regulations, e.g., without filter 155. As such, filter 155 may be implemented with fewer components, lower cost components, or might not be included in circuit 200 based on improvements in out-of-band emission filtering achieved by coupling capacitor 220 to terminals (e.g., quarter tap terminals) of inductor 222.

FIG. 3 illustrates aspects of conductive features used in a balun circuit of a system in accordance with an embodiment. FIG. 3 shows architecture 300, which includes and references elements of system 100 of FIG. 1 and circuit 200 of FIG. 2. Architecture 300 includes inductors 222 and 224, capacitors 305 and 306, and various other elements of a system-on-chip (SoC) (e.g., an integrated circuit), such as pins, pads, and/or ports, vias, and traces of the SoC. Architecture 300 may represent a physical implementation of elements of a transceiver system, such as balun 145, of system 100 and of circuit 200 of FIGS. 1 and 2, respectively.

Architecture 300 depicts an example layout of conductive features, and couplings and/or connections thereof, inside and/or on-top of a chip (e.g., silicon die). The embodiment shown in FIG. 3 implements 6 metal layers (MET1-MET6) and a top layer (METTOP) (top layer 391), where MET6 (top-inner layer 392) it is at a higher level (closer to METTOP and farthest from the substrate) than MET5, MET 5 is at a higher level than MET4, MET4 is at a higher level than MET3, MET3 is at a higher level than MET2, and MET2 is at a higher level than MET1. In some embodiments, inner layer 393 of legend 390 may be representative of one or more of MET1-MET5. Similarly, inner layer 394 of legend 390 may be representative of one or more of MET1-MET5. Some embodiments may be implemented with a different number of metal layers (e.g., more than 6, or less than 6).

The features included in architecture 300 may include traces of conductive material etched or embedded (e.g., in an integrated circuit—also referred to as chip) on one or more layers of the chip (e.g., MET1-MET6 (i.e., six inner layers), METTOP (i.e., a top layer)). Such features, when coupled together and provided signals from an amplifier (e.g., amplifier 142), may perform functionality of balun 145, including filtering noise and harmonics emitted and/or to be emitted by an antenna (e.g., antenna 160). In some embodiments, the features included in architecture 300 may include metal tracks etched or embedded in a chip on or more layers of the chip. In some embodiments, while not illustrated, architecture 300 may include various vias configured to couple elements of architecture 300 between one or more layers of the chip. For example, architecture 300 may include vias 340, 341, 342, 343, and 344, which may be configured to couple portions (e.g., metal tracks, conductive features) of inductor 224 to other portions of inductor 224 across one or more layers of the chip.

Architecture 300 includes inductor 222, inductor 224, and capacitors 305 and 306. Each of inductor 222, inductor 224, capacitor 305, and capacitor 306 may include a set of conductive features including two terminals. Each set of conductive features may be included on one or more layers of the chip. In some embodiments, inductors 222 and 224 may be located on a first inner layer of the chip, top-inner layer 392, and the top layer 391 (e.g., MET6 and METTOP), capacitors 305 and 306 may be located on one or more other inner layers of the chip (e.g., layers beneath MET, such as MET1, MET2, MET3, MET4, MET5, e.g., inner layer 393), and various terminals (e.g., pins, pads, ports) (e.g., terminals 211, 212, 213, 214, 215, 216) may be located on a top layer of the chip (e.g., METTOP, e.g., top layer 391). In some such embodiments, the sets of conductive features may span multiple layers of the chip, including combinations and variations thereof. For example, inductors 222 and 224 may be located on one or more inner layers of the chip, such as MET6 (e.g., top-inner layer 391), instead of including portions located on the top layer of the chip. In some such embodiments, various vias (e.g., vias 340, 341, 342, 343, and 344) may be included that span multiple layers of the chip.

In some embodiments, inductor 222 includes a first terminal coupled to terminal 211 and a second terminal coupled to terminal 215. In some embodiments, inductor 222 may be arranged in a ring or circular formation on top-inner layer 392 and the top layer 391 of the chip (e.g., MET6 and METTOP). In some embodiments, inductor 222 may be arranged in a C-shaped formation on the top-inner layer 392 and the top layer 391 of the chip, such that the conductive features do not form an enclosed ring.

In some embodiments, inductor 224 includes a first terminal coupled to terminal 216 and a second terminal coupled to ground terminal 148. In some embodiments, inductor 224 includes an outer portion of the set of conductive features located on the top-inner layer and the top layer 391 of the chip (e.g., MET6 and METTOP) that couples to terminals 216 and to ground terminal 148, which may also be located on the top layer 391 of the chip (e.g., METTOP), and an inner portion of the set of conductive features located on the top-inner layer of the chip that couples to the outer portion through one or more vias extending between one or more layers of the chip. In some such embodiments, the inner portion of the conductive features may form the ring or C-shaped formation of inductor 224, and the inner portion may be surrounded by or enclosed by the set of conductive features that form inductor 222. Further, in some such embodiments, the outer portion of the conductive features may partially surround both the set of conductive features of inductor 222 and the inner portion of the set of conductive features of inductor 224. In this way, the set of conductive features of inductor 222 may be disposed of and positioned such that the set of conductive features are located in between the inner and outer portions of conductive features of inductor 224. In some embodiments, the set of conductive features of inductor 224 may be located on and arranged within multiple layers of the chip.

In some embodiments, capacitor 305 includes a first terminal (e.g., a stub) coupled to terminal 212 and a second terminal coupled to a first terminal of capacitor 306, and capacitor 306 includes a second terminal coupled to terminal 214. In some embodiments, the sets of conductive features that form capacitors 305 and 306 may be located on one or more inner layers of the chip, such as inner layer 393 (e.g., one or more of MET1-MET5). In some embodiments, capacitors 305 and 306 may be located on the same layers, different layers, or a combination or variation of layers. In some embodiments, capacitors 305 and 306 may be disposed of and positioned such that capacitors 305 and capacitors 306 are in an inner-most position relative to inductors 222 and 224 and are enclosed by inductors 222 and 224.

In some embodiments, capacitors 305 and 306 may represent a split-capacitor device (e.g., capacitor 220) including two (e.g., or more) individual capacitors coupled in series with each other to minimize the amount of lead inductance to the tap terminals of balun 145 (e.g., terminals 212 and 214).

In some such embodiments, capacitors 305 and 306 may be capacitors having the same size and capacitance. In some such embodiments, the dimensions (e.g., width, length) of the first and second terminals of capacitors 305 and 306 may be smaller than terminals of a single capacitor including a first terminal coupled to terminal 212 and a second terminal coupled to terminal 214. In some embodiments, capacitors 305 and 306 may be replaced by a single capacitor. In some embodiments, additional capacitors coupled in series with capacitors 305 and 306 may be included. In some embodiments, capacitors 305 and 306 may include two plates each. In some such embodiments, a first plate of each capacitor may be implemented in the first layer of the chip, while the second plate of each capacitor may be implemented on a layer beneath the first layer of the chip (e.g., inner layer 393).

Terminals 212 and 214 may represent tap points located on the top layer 391 (e.g., METTOP) or the top-inner layer 392 (MET6) of the chip that provide connection points to inductor 222 at a first point and a second point, respectively. In some embodiments, other layers (e.g., MET1, MET2, MET3, MET4, MET5) may be used.

The portion of the set of conductive features of inductor 222 between terminal 211 and 212 may be referred to as inductor portion 222-2, the portion of the set of conductive features of inductor 222 between terminals 212 and 214 may be referred to as inductor portion 222-1, and the portion of the set of conductive features of inductor 222 between terminals 214 and 215 may be referred to as inductor portion 222-3. Inductor 222 may also include a center tap terminal 213 located on the top-inner layer 392 and the top layer 391 of the chip that provides a connection point to inductor 222 at a midpoint of inductor 222. In various embodiments, a power supply that provides a supply power (e.g., supply power 104) may be coupled at center tap terminal 213.

In some embodiments, the locations of terminals 212 and 214 along the set of conductive features of inductor 222 may be determined based on the target transmission frequency of an antenna (e.g., antenna 160) configured to couple to pin 154 of balun 145 and based on desired filtering of a target harmonic frequency of the target transmission frequency (e.g., the third odd-harmonic frequency of the target transmission frequency). Additionally, the capacitance values of capacitors 305 and 306, among other capacitors (e.g., capacitor 146), may be determined based on the target transmission frequency and the target harmonic frequency of the target transmission frequency which has to be attenuated.

In some embodiments, the sets of conductive features that form inductors 222 and 224 and capacitors 305 and 306 may be positioned such that the sets of conductive features are symmetrical with respect to the x-axis relative to a top-down view that intersects center tap terminal 213. Further, the sets of conductive features as well as terminals 212 and 214 may be positioned such that the sets of conductive features and the terminals are symmetrical with respect to the x-axis based on terminal 212 being positioned equal distances from terminal 211 and center tap terminal 213 and based on terminal 214 being positioned equal distances from terminal 215 and center tap terminal 213. The sets of conductive features as well as terminals 212 and 214 may be positioned asymmetrically with respect to the x-axis if terminals 212 and 214 are positioned with different respective distances to such terminals. In some such embodiments, the sets of conductive features may be asymmetrical with respect to the y-axis relative to the top-down view. In this way, in some embodiments, a midline 315 may intersect the center tap terminal 213 and divide balun 145 into two portions across the x-axis that are a mirror image of each other.

In this arrangement, capacitors 305 and 306 may form a split-capacitor that functions as a filter in balun 145 capable of filtering emissions at one or more harmonic frequencies associated with a transmission frequency. Advantageously, the capacitors may be sized and positioned to reduce the distance from the capacitors to the turns of balun 145 and improve filtering capability of balun 145, which may advantageously allow for filtering out-of-band emissions (e.g., to abide by RF communication regulations) as well as reducing in size and/or complexity or elimination on-board/off-chip filters such as filter 145.

In other examples, architecture 300 may include additional or fewer components, which may be arranged in a different layout. For example, the positioning of various conductive features may be different. Nevertheless, inductors 222 and 224 and one or more capacitors (e.g., capacitor 220, capacitors 305 and 306) may be included to filter harmonic frequency emissions produced by an antenna.

In some embodiments, elements of architecture 300, such as inductors 222 and 224, capacitors 305 and 306, and other electrical components and circuits may be implemented as metal tracks. For example, inductor portions 222-1, 222-2, and 222-3 may each include a metal track, or a portion of a metal track, that forms inductor 222. In some such embodiments, inductor 222 may include four metal tracks, such as a first metal track 321 coupled between center tap terminal 213 and terminal 212, a second metal track 322 coupled between center tap terminal 213 and terminal 214, a third metal track 320 coupled between terminal 212 and terminal 211, and a fourth metal track 323 coupled between terminal 214 and terminal 215. Each of the metal tracks may be implemented on the same layer or on different layers, as well as variations and combinations thereof. In the embodiment illustrated in FIG. 3, metal tracks 320, 321, 322, and 323 are all implemented in top-inner layer 392.

Similarly, inductor 224 may be implemented as metal tracks spanning one or more layers of the chip and going through one or more vias. For example, in the embodiment illustrated in FIG. 3, inductor 224 includes a first metal track 330 coupled between ground terminal 148 and via 343, metal track 318 from via 343 to via 344, metal track 332 (which includes metal track portion 331 and is on the same layer as metal track portion 331) from via 344 to via 340, metal track 333 from via 340 to via 341, metal track 319 from via 341 to via 342, and metal track 334 from via 342 to terminal 156.

In the embodiment illustrated in FIG. 3, metal tracks 320, 321, 322, 323, 330, 332, and 334 are implemented in top-inner layer 392, and metal tracks 318, 319, and 333 are implemented in inner layer 394.

In some embodiments, the metal tracks of inductor 222 and the first, third, and fifth metal tracks of inductor 224 may all be implemented in the same metal layer, and the metal tracks of inductor 224 may all be implemented in the same metal layer.

In some embodiments, architecture 300 may include metal tracks to couple portions of inductor 222 to capacitors 305 and 306. For example, architecture 300 may include metal track 328 coupling inductor 222, at terminal 212, to terminal 307, which is coupled to (e.g., a top plate of) capacitor 305 via metal track 325. Metal track 326 couples (e.g., top plates of) capacitors 305 and 306 together. Metal track 327 couples (e.g., a top plate of) capacitor 306 to terminal 308 to which inductor 222 is coupled via metal track 329 at terminal 214. In some such embodiments, tracks 328 and 329 may be tracks of equal length.

In some embodiments, tracks 325, 326, and 327 may be implemented in the same layer (e.g., such as the same layer of the top plates of capacitors 305 and 306), although other layers may be used.

In some embodiments, tracks 328 and 329 may be implemented in the same layer, such as layer 391 (although other layers may be used).

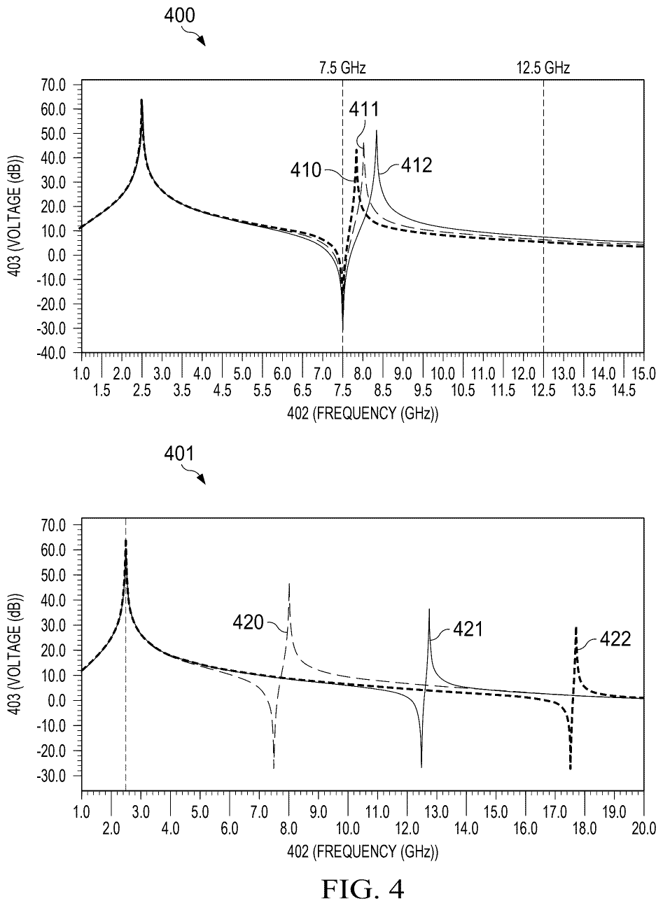

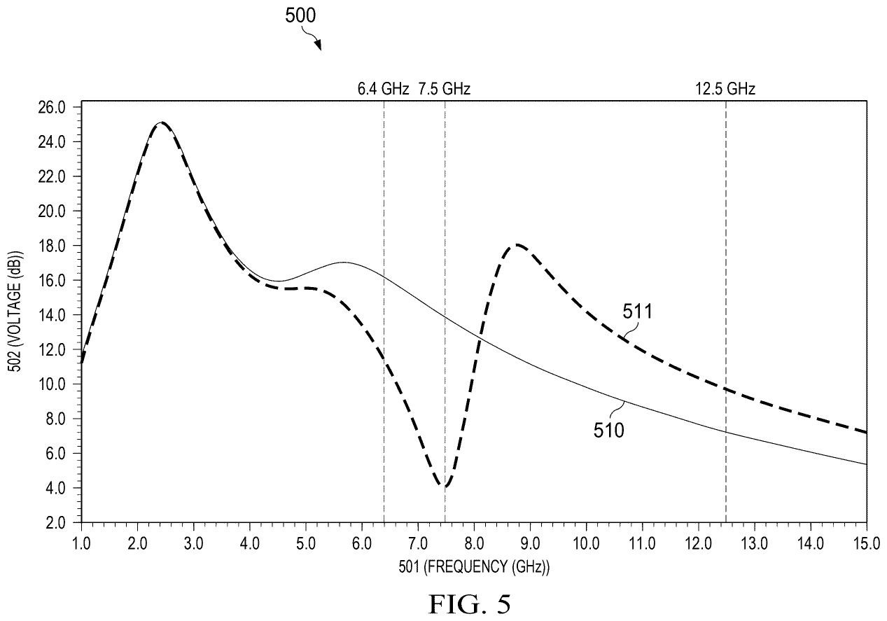

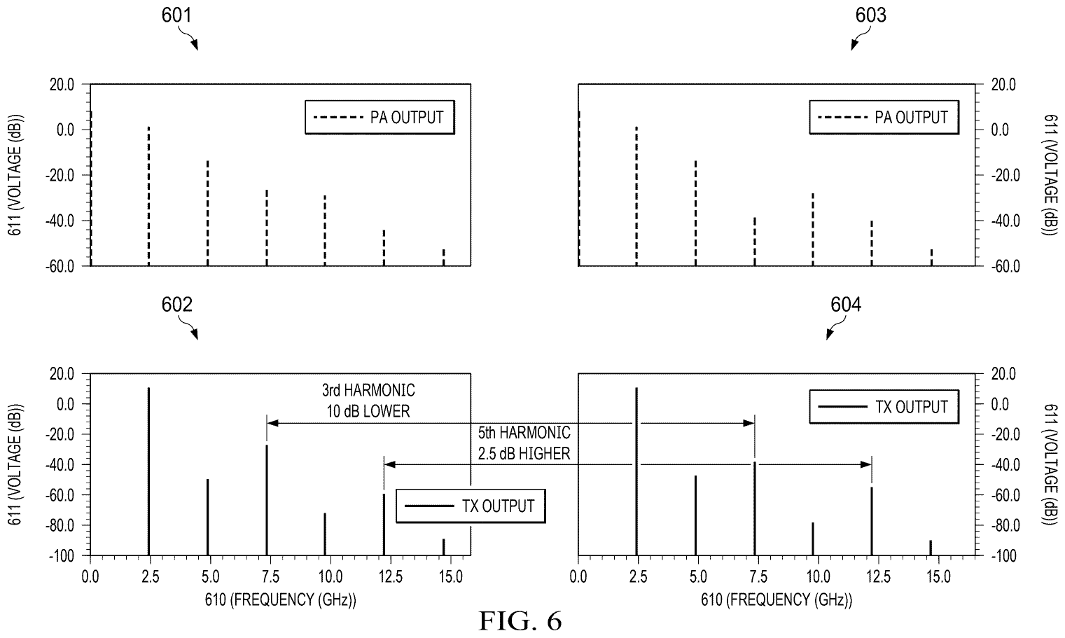

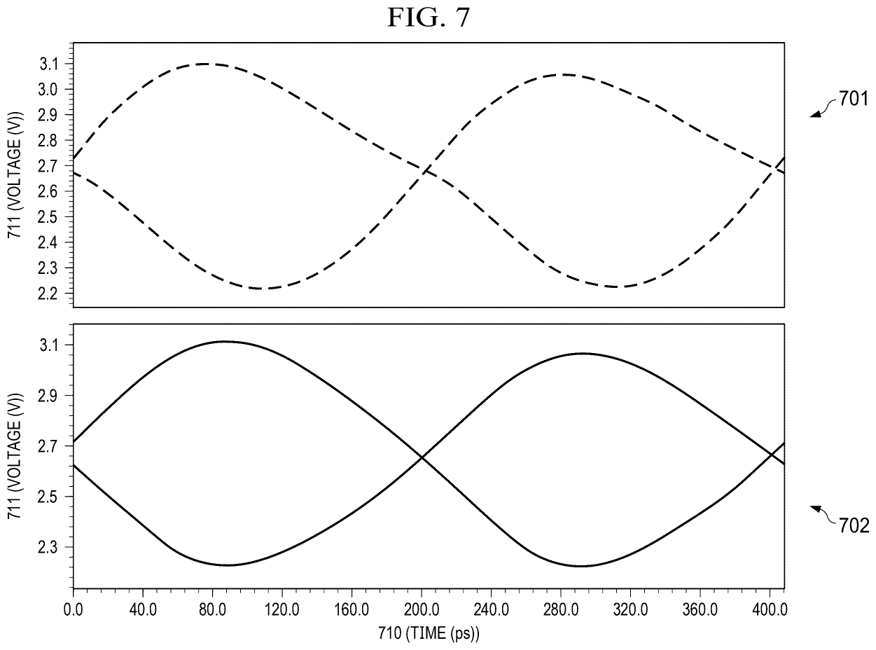

FIGS. 4, 5, 6, and 7 illustrate example graphical representations of waveforms produced by a transceiver system in accordance with an embodiment. FIG. 4 shows graphical representations 400 and 401, which may include various waveforms produced by a transceiver system (e.g., system 100 of FIG. 1, circuit 200 of FIG. 2) with respect to frequency 402 and voltage 403. FIG. 5 shows graphical representation 500, which may include various waveforms produced by a transceiver system with respect to frequency 501 and voltage 502. FIG. 6 shows graphical representations 601, 602, 603, and 604. FIG. 7 shows graphical representations 701 and 702. Each figure may reference elements of system 100 of FIG. 1 and/or elements of circuit 200 of FIG. 2.

Referring first to FIG. 4, graphical representation 400 includes waveforms 410, 411, and 412 representative of gain of signals transmitted by an antenna (e.g., antenna 160) of a transceiver system across varying frequencies. More specifically, waveform 410 may include output transmissions of the antenna based on selecting a first distance (e.g., n=0.4) between a terminal connection terminal of inductor 222 (e.g., terminal 211) and a first tap terminal of inductor 222 (e.g., terminal 212) relative to the distance between a first tap terminal of inductor 222 (e.g., terminal 212) and a second tap terminal of inductor 222 (e.g., terminal 212), waveform 411 may include output transmissions of the antenna based on selecting a second distance (e.g., n=0.5) between the same terminals of inductor 222 as mentioned above, and waveform 412 may include output transmissions of the antenna based on selecting a third distance (e.g., n=0.6) between the same terminals of inductor 222 as mentioned above. In each waveform, the antenna signal may include a first pole at a target transmission frequency (e.g., approximately 2.5 GHZ), a second pole at another transmission frequency based on the distance, n, and capacitance values of capacitors 146 and 220, and a zero at another transmission frequency (e.g., approximately 7.5 GHZ) based on the distance and capacitance values. In some embodiments, a distance of n=0.5 may be selected to realize the lowest gain at the fifth harmonic frequency of the target transmission frequency relative to other distances, which is illustrated by waveform 410 (i.e., gain at approximately 12.5 GHZ=5.46 dB).

Based on determining that n=0.5 may produce the lowest gain at the fifth harmonic frequency of the target transmission frequency, different capacitance values of capacitor 220 may be selected to realize a zero at another harmonic frequency of the target transmission frequency. In graphical representation 401, waveforms 420, 421, and 422 demonstrate gain of signals transmitted by the antenna across varying frequencies based on n=0.5 and based on different capacitance values of capacitor 220. More specifically, waveform 420 may include transmission emissions produced by antenna 160 when n=0.5 and capacitor 220 includes a capacitance of 3.2 pF, waveform 421 may include transmission emissions produced by antenna 160 when n=0.5 and capacitor 220 includes a capacitance of 1.2 pF, and waveform 422 may include transmission emissions produced by antenna 160 when n=0.5 and capacitor 220 includes a capacitance of 0.6 pF. As illustrated in graphical representation 401, waveform 420 may show a zero at the third harmonic frequency of the target transmission frequency, waveform 421 may show a zero at the fifth harmonic frequency of the target transmission frequency, and waveform 422 may show a zero at the seventh harmonic frequency of the target transmission frequency. Additionally, the capacitance of capacitor 146 may be based on the capacitance of capacitor 220 and may be selected to produce a pole at the target transmission frequency.

Referring next to FIG. 5, graphical representation 500 includes waveforms 510 and 511 that include results corresponding to transmission gain measured across outputs 205 and 206 of amplifier 142. Waveform 510 may demonstrate such results produced without including capacitor 220 in balun 145, while waveform 511 may demonstrate such results when capacitor 220 is included in balun 145 (and with n=0.5 and capacitance of capacitor 220=3.2 pF) according to various embodiments of the present disclosure as described herein. As illustrated by waveforms 510 and 511, the gain at the third harmonic frequency (approximately 7.5 GHZ) of the target transmission frequency (approximately 2.5 GHZ) may be reduced by 10 dB based on capacitor 220, and the gain at the fifth harmonic frequency (approximately 12.5 GHZ) of the target transmission frequency may be increased by 2.5 dB. Additionally, the gain at approximately 6.4 GHz may be reduced by almost 5 dB. Advantageously, not only may the gain of the third harmonic frequency be reduced to improve filtering capabilities by balun 145, but also the gain at the operating frequency of VCO 116 may be reduced, which may advantageously reduce VCO spur coupling through the transmission path to antenna 160.

Referring next to FIG. 6, graphical representations 601 and 602 include results corresponding to signal levels measured at outputs 205 and 206 of amplifier 142 and at antenna 160, respectively, in a system without capacitor 220, and graphical representations 603 and 604 include results corresponding to signal levels measured at outputs 205 and 206 of amplifier 142 and at antenna 160, respectively, in a system that includes capacitor 220 in balun 145. As illustrated, the gain at the third harmonic frequency (e.g., approximately 7.5 GHz) may be lower in a system including capacitor 220 than the gain at the third harmonic frequency produced by a system that does not include capacitor 220.

Referring next to FIG. 7, graphical representation 701 includes results produced at outputs 205 and 206 of amplifier 142 based on inputting a sine wave at inputs of amplifier 142 in a system that does not include capacitor 220, and graphical representation 702 includes results produced at outputs 205 and 206 of amplifier 142 based on inputting the same sine wave at inputs of amplifier 142 when balun 145 coupled at outputs 205 and 206 includes capacitor 220. As illustrated, graphical representation 702 may include result waveforms that have less distortion than the result waveforms of graphical representation 701 due to attenuation of the third harmonic of the transmit frequency.

Example embodiments of the present disclosure are summarized here. Other embodiments can also be understood from the entirety of the specification and the claims filed herein.

Example 1. A circuit including: a first input terminal configured to be coupled to a first terminal of a first capacitor; a second input terminal configured to be coupled to a second terminal of the first capacitor; a balun including: a primary inductor that includes: a first terminal coupled to the first input terminal, a second terminal coupled to the second input terminal, a first inductive portion coupled between the first terminal of the primary inductor and a first intermediate terminal, a second inductive portion coupled between the second terminal of the primary inductor and a second intermediate terminal, and a third inductive portion coupled between the first and second intermediate terminals, and a secondary inductor that includes a first terminal coupled to a ground terminal; and a second capacitor coupled between the first and second intermediate terminals.

Example 2. The circuit of example 1, further including an amplifier having a first output coupled to the first input terminal, and a second output coupled to the second input terminal.

Example 3. The circuit of one of examples 1 or 2, further including a filter coupled to a second terminal of the secondary inductor.

Example 4. The circuit of one of examples 1 to 3, further including an antenna coupled to the filter.

Example 5. The circuit of one of examples 1 to 4, where the antenna is designed to operate in a 2.4 GHz band.

Example 6. The circuit of one of examples 1 to 5, where the antenna is designed to operate in a WiFi application in accordance with an IEEE 802.11.ax protocol.

Example 7. The circuit of one of examples 1 to 6, where the primary inductor includes a center-tap terminal located at a midpoint between the first input terminal and the second input terminal, where the first intermediate terminal is located a first distance from the center-tap terminal in a first direction, and where the second intermediate terminal is located a second distance from the center-tap terminal in a second direction different from the first direction.

Example 8. The circuit of one of examples 1 to 7, where the primary inductor is implemented with metal tracks, where the first distance corresponds to a first length of a first portion of the metal tracks that is connected from the center-tap terminal to the first intermediate terminal, and where the second distance corresponds to a second length of a second portion of the metal tracks that is connected from the center-tap terminal to the second intermediate terminal.

Example 9. The circuit of one of examples 1 to 8, where a midline that intersects the center-tap terminal divides the balun and the second capacitor into a first portion and a second portion, and where the first portion is a mirror image of the second portion.

Example 10. The circuit of one of examples 1 to 9, where the primary inductor is implemented with metal tracks, where the first distance corresponds to a first length of a first portion of the metal tracks that is connected from the center-tap terminal to the first intermediate terminal, and where the second distance corresponds to a second length of a second portion of the metal tracks that is connected from the center-tap terminal to the second intermediate terminal.

Example 11. The circuit of one of examples 1 to 10, where the first distance and the second distance are equal.

Example 12. The circuit of one of examples 1 to 11, where the first distance and the second distance are not equal.

Example 13. The circuit of one of examples 1 to 12, where the first distance and the second distance are selected to cause a notch in a frequency response at a first frequency corresponding to a first odd-order harmonic of a transmission frequency.

Example 14. The circuit of one of examples 1 to 13, where the second capacitor includes a capacitance value based on first and second distances.

Example 15. The circuit of one of examples 1 to 14, where the capacitance value of the second capacitor is based on the first frequency.

Example 16. The circuit of one of examples 1 to 15, where the transmission frequency includes a first frequency range including a frequency between 2.412-2.484 GHZ.

Example 17. The circuit of one of examples 1 to 16, where the first odd-order harmonic includes a third harmonic of the transmission frequency, where the third harmonic includes a second frequency range including a frequency of 7.344 GHZ.

Example 18. The circuit of one of examples 1 to 17, where the first frequency range corresponds to a frequency range of a Wi-Fi communication protocol.

Example 19. The circuit of one of examples 1 to 18, where the first frequency range corresponds to a frequency range of a Bluetooth Classic or Bluetooth Low Energy (BLE) communication protocol.

Example 20. The circuit of one of examples 1 to 19, further including the first capacitor coupled between the first and second input terminals.

Example 21. The circuit of one of examples 0 to 20, where the first capacitor includes a capacitance value based on the capacitance value of the second capacitor.

Example 22. A circuit including: a first capacitor including first and second terminals, and a first set of conductive features; a first input terminal coupled to the first terminal of the first capacitor; a second input terminal coupled to the second terminal of the first capacitor; a balun including: a secondary inductor that includes: a first terminal coupled to a ground terminal; and a second set of conductive features; and a primary inductor that includes: a first terminal coupled to the first input terminal; a second terminal coupled to the second input terminal; and a third set of conductive features proximate to the second set of conductive features of the secondary inductor; and a second capacitor that includes a fourth set of conductive features proximate to the first and second sets of conductive features and disposed such that the fourth set of conductive features are positioned within an area inside the second and third sets of conductive features; where the third set of conductive features of the primary inductor includes: a first subset of conductive features coupled between the first terminal of the primary inductor and a first intermediate terminal; a second subset of conductive features coupled between the second terminal of the primary inductor and a second intermediate terminal; and a third subset of conductive features coupled between the first and second intermediate terminals; and where the fourth set of conductive features of the second capacitor are coupled between the first and second intermediate terminals.

Example 23. The circuit of example 22, further including a filter coupled to a second terminal of the secondary inductor.

Example 24. The circuit of one of examples 22 or 23, further including an antenna coupled to the filter.

Example 25. The circuit of one of examples 22 to 24, where the antenna is designed to operate in a frequency range that includes a frequency range from 2.40 GHz to 2.48 GHz.

Example 26. The circuit of one of examples 22 to 25, where the antenna is designed to operate in a frequency range included in a range between 3.1 GHz and 10.6 GHz.

Example 27. The circuit of one of examples 22 to 26, further including an amplifier having a first output coupled to the first input terminal, and a second output coupled to the second input terminal.

Example 28. The circuit of one of examples 22 to 27, where the primary inductor includes a center-tap terminal located at a midpoint between the first input terminal and the second input terminal, where the first intermediate terminal is located a first distance from the center-tap terminal in a first direction, and where the second intermediate terminal is located a second distance from the center-tap terminal in a second direction different from the first direction.

Example 29. The circuit of one of examples 22 to 28, where a midline that intersects the center-tap terminal divides the balun and the second capacitor into a first portion and a second portion, and where the first portion is a mirror image of the second portion.

Example 30. The circuit of one of examples 22 to 29, where the first distance and the second distance are equal.

Example 31. The circuit of one of examples 22 to 30, where the first distance and the second distance are not equal.

Example 32. The circuit of one of examples 22 to 31, where the second, third, and fourth sets of conductive features are implemented in a set of traces of an integrated circuit, and where the set of traces is symmetrical relative to an x-axis, relative to a top-down view of the integrated circuit, that interests the center-tap terminal.

Example 33. The circuit of one of examples 22 to 32, where the second, third, and fourth sets of conductive features are implemented in a set of traces of an integrated circuit, and where the set of traces is asymmetrical relative to a y-axis, relative to a top-down view of the integrated circuit, that intersects a first plate of the second capacitor.

Example 34. The circuit of one of examples 22 to 33, where: the second capacitor includes a split-capacitor including a third capacitor and a fourth capacitor coupled together in series; the third capacitor includes a first subset of the fourth set of conductive features that includes a first terminal and a second terminal; the fourth capacitor includes a second subset of the fourth set of conductive features that includes a third terminal and a fourth terminal; and the second terminal is coupled to the third terminal.

Example 35. The circuit of one of examples 22 to 34, where the third set of conductive features are disposed such that a portion of the third set of conductive features is between a first portion of the second set of conductive features and a second portion of the second set of conductive features.

Example 36. An integrated circuit including: a balun including: a primary inductor that includes: a center-tap terminal, first and second input terminals, first and second intermediate terminals, a first metal track coupled between the center-tap terminal and the first intermediate terminal, a second metal track coupled between the center-tap terminal and the second intermediate terminal, a third metal track coupled between the first intermediate terminal and the first input terminal, and a fourth metal track coupled between the second intermediate terminal and the second input terminal, a secondary inductor that includes a ground terminal and an output terminal; and a first capacitor coupled between the first and second intermediate terminals.

Example 37. The integrated circuit of example 36, where the first, second, third, and fourth metal tracks are implemented in a same metal layer of the integrated circuit.

Example 38. The integrated circuit of one of examples 36 or 37, where the secondary inductor includes: third, fourth, fifth, and sixth intermediate terminals, each of the third, fourth, fifth, and sixth terminals including a respective via; a fifth metal track coupled between the ground terminal and the third intermediate terminal; a sixth metal track coupled between the third intermediate terminal and the fourth intermediate terminal; a seventh metal track coupled between the fourth intermediate terminal and the fifth intermediate terminal; an eighth metal track coupled between the fifth intermediate terminal and the sixth intermediate terminal; and a ninth metal track coupled between the sixth intermediate terminal and the output terminal.

Example 39. The integrated circuit of one of examples 36 to 38, where the first, second, third, fourth, fifth, seventh, and ninth metal tracks are implemented in a first metal layer of the integrated circuit, and where the sixth and eighth metal track are implemented in a second metal layer of the integrated circuit.

Example 40. The integrated circuit of one of examples 36 to 39, where a portion of the first metal track is disposed between a portion of the seventh metal track and a portion of the ninth metal track.

Example 41. The integrated circuit of one of examples 36 to 40, where a first plate of the first capacitor is implemented in the first metal layer, and where the first plate is disposed between the first and second metal tracks.

Example 42. The integrated circuit of one of examples 36 to 41, where a first plate of the first capacitor is disposed between the first and second metal tracks.

Example 43. The integrated circuit of one of examples 36 to 42, where the first capacitor is a split capacitor that includes a second capacitor and a third capacitor, where the integrated circuit further includes: a fifth track coupled between the first intermediate terminal and a first plate of the second capacitor; a sixth track coupled between the first plate of the second capacitor and a first plate of the third capacitor; and a seventh track coupled between the first plate of the third capacitor and the second intermediate terminal.

Example 44. The integrated circuit of one of examples 36 to 43, where the first and second metal tracks are metal tracks of equal length.

Example 45. An electronic circuit including: a phase-locked loop (PLL) circuit; and a transmitter circuit coupled to the PLL circuit, where the transceiver circuit includes: an amplifier; and an impedance-matching circuitry coupled to the amplifier circuitry, where the impedance-matching circuitry includes: a first input terminal configured to be coupled to a first terminal of a first capacitor; a second input terminal configured to be coupled to a second terminal of the first capacitor; and a balun including: a primary inductor that includes: a first terminal coupled to the first input terminal, a second terminal coupled to the second input terminal, a first inductive portion coupled between the first terminal of the primary inductor and a first intermediate terminal, a second inductive portion coupled between the second terminal of the primary inductor and a second intermediate terminal, and a third inductive portion coupled between the first and second intermediate terminals, and a secondary inductor that includes a first terminal coupled to a ground terminal; and a second capacitor coupled between the first and second intermediate terminals.

Example 46. The electronic circuit of example 45, further including an antenna coupled to the impedance matching circuitry.

Example 47. The electronic circuit of one of examples 45 or 46, where the antenna is designed to operate in a 2.4 GHz band.

Example 48. The electronic circuit of one of examples 45 to 47, where the primary inductor includes a center-tap terminal located at a midpoint between the first input terminal and the second input terminal, where the first intermediate terminal is located a first distance from the center-tap terminal in a first direction, and where the second intermediate terminal is located a second distance from the center-tap terminal in a second direction different from the first direction.

Example 49. The electronic circuit of one of examples 45 to 48, where a midline that intersects the center-tap terminal divides the balun and the second capacitor into a first portion and a second portion, and where the first portion is a mirror image of the second portion.

Example 50. The electronic circuit of one of examples 45 to 49, where the first distance and the second distance are selected to cause a notch in a frequency response at a first frequency corresponding to a first odd-order harmonic of a transmission frequency.

Example 51. The electronic circuit of one of examples 45 to 50, where the first distance and the second distance are selected based on a target gain at a second frequency.

Example 52. The electronic circuit of one of examples 45 to 51, where the PLL circuit includes a voltage-controlled oscillator (VCO) circuit designed to operate at a frequency range including the second frequency, and where the second frequency includes a frequency of 6.4 GHz.

Example 53, The electronic circuit of one of examples 45 to 52, where the second frequency is 6.4 GHz.

While some examples provided herein are described in the context of a transceiver system, circuit, sub-circuit, component, device, element, architecture, or environment, the systems, circuits, and methods described herein are not limited to such embodiments and may apply to a variety of other processes, systems, applications, devices, and the like.

The phrases “in some embodiments,” “according to some embodiments,” “in the embodiments shown,” “in other embodiments,” and the like generally mean the particular feature, structure, or characteristic following the phrase is included in at least one implementation of the present technology, and may be included in more than one implementation. In addition, such phrases do not necessarily refer to the same embodiments or different embodiments.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or elements are presented in a given order, alternative implementations may perform routines having steps, or employ systems having elements or components, in a different order, and some processes or elements may be deleted, moved, added, subdivided, combined, and/or modified to provide alternative or subcombinations. Each of these processes or elements may be implemented in a variety of different ways. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated.

What is claimed is:

1. A circuit comprising:
a first input terminal configured to be coupled to a first terminal of a first capacitor;
a second input terminal configured to be coupled to a second terminal of the first capacitor;
a balun comprising:
a primary inductor that includes:
a first terminal coupled to the first input terminal,
a second terminal coupled to the second input terminal,
a first inductive portion coupled between the first terminal of the primary inductor and a first intermediate terminal,
a second inductive portion coupled between the second terminal of the primary inductor and a second intermediate terminal, and
a third inductive portion coupled between the first and second intermediate terminals, and
a secondary inductor that includes a first terminal coupled to a ground terminal; and
a second capacitor coupled between the first and second intermediate terminals.

2. The circuit of claim 1, further comprising an amplifier having a first output coupled to the first input terminal, and a second output coupled to the second input terminal.

3. The circuit of claim 1, further comprising a filter coupled to a second terminal of the secondary inductor.

4. The circuit of claim 3, further comprising an antenna coupled to the filter.

5. The circuit of claim 4, wherein the antenna is designed to operate in a 2.4 GHz band.

6. The circuit of claim 4, wherein the antenna is designed to operate in a WiFi application in accordance with an IEEE 802.11.ax protocol.

7. The circuit of claim 1, wherein the primary inductor comprises a center-tap terminal located at a midpoint between the first input terminal and the second input terminal, wherein the first intermediate terminal is located a first distance from the center-tap terminal in a first direction, and wherein the second intermediate terminal is located a second distance from the center-tap terminal in a second direction different from the first direction.

8. The circuit of claim 7, wherein the primary inductor is implemented with metal tracks, wherein the first distance corresponds to a first length of a first portion of the metal tracks that is connected from the center-tap terminal to the first intermediate terminal, and wherein the second distance corresponds to a second length of a second portion of the metal tracks that is connected from the center-tap terminal to the second intermediate terminal.

9. The circuit of claim 8, wherein a midline that intersects the center-tap terminal divides the balun and the second capacitor into a first portion and a second portion, and wherein the first portion is a mirror image of the second portion.

10. The circuit of claim 8, wherein the primary inductor is implemented with metal tracks, wherein the first distance corresponds to a first length of a first portion of the metal tracks that is connected from the center-tap terminal to the first intermediate terminal, and wherein the second distance corresponds to a second length of a second portion of the metal tracks that is connected from the center-tap terminal to the second intermediate terminal.

11. The circuit of claim 7, wherein the first distance and the second distance are equal.

12. The circuit of claim 7, wherein the first distance and the second distance are not equal.

13. The circuit of claim 7, wherein the first distance and the second distance are selected to cause a notch in a frequency response at a first frequency corresponding to a first odd-order harmonic of a transmission frequency.

14. The circuit of claim 7, wherein the second capacitor includes a capacitance value based on first and second distances.

15. The circuit of claim 13, wherein the capacitance value of the second capacitor is based on the first frequency.

16. The circuit of claim 13, wherein the transmission frequency comprises a first frequency range including a frequency between 2.412-2.484 GHz.

17. The circuit of claim 16, wherein the first odd-order harmonic comprises a third harmonic of the transmission frequency, wherein the third harmonic includes a second frequency range including a frequency of 7.344 GHz.

18. The circuit of claim 16, wherein the first frequency range corresponds to a frequency range of a Wi-Fi communication protocol.

19. The circuit of claim 16, wherein the first frequency range corresponds to a frequency range of a Bluetooth Classic or Bluetooth Low Energy (BLE) communication protocol.

20. The circuit of claim 7, further comprising the first capacitor coupled between the first and second input terminals.

21. The circuit of claim 20, wherein the first capacitor includes a capacitance value based on the capacitance value of the second capacitor.
